(19) United States
(12) Patent Application Publication
(10) Pub. No.: US 2010/0148264 A1
(43) Pub. Date: Jun. 17, 2010

(54) ELECTROSTATIC DISCHARGE PROTECTION DEVICE AND METHOD OF FABRICATING THE SAME

(75) Inventors: Hsin-Yen Hwang, Hsinchu County (TW); Tien-Hao Tang, Hsinchu City (TW)

Correspondence Address: J C PATENTS, 4 VENTURE, SUITE 250, IRVINE, CA, 92618, US

(73) Assignee: UNITED MICROELECTRONICS CORP., Hsinchu (TW)

(21) Appl. No.: 12/333,596

(22) Filed: Dec. 12, 2008

(51) Int. Cl. H01L 21/336; H01L 29/78

(52) U.S. Cl. 257/355; 438/306; 257/E29.255; 257/E21.409

(57) ABSTRACT

An ESD protection device including a substrate, a gate structure, a source region, a drain region and a first implanted region is provided. The gate structure includes a gate dielectric layer and a gate sequentially disposed on the substrate. The source region and the drain region are disposed in the substrate beside the gate structure. The first implanted region has the same conductivity type as the drain region. The first implanted region is disposed below the drain region, and the border thereof does not exceed the border of the drain region.

### BACKGROUND OF THE INVENTION

1. Field of Invention

The present invention relates to an integrated circuit and a method of fabricating the same, and more generally to an electrostatic discharge (ESD) protection device and a method of fabricating the same.

2. Description of Related Art

ESD is the main factor of electrical overstress (EOS) which causes damage to most of electronic devices or systems. Such damage can result in the permanent damage of a semiconductor device and a computer system, so that the circuit function of an IC is affected and the operation of an electronic product is abnormal. Accordingly, a metal oxide semiconductor field effect transistor (MOSFET) is disposed between the input pad of an IC and the internal circuit to serve as an ESD protection device.

Generally speaking, an ESD pulse generates a lot of heat in the MOSFET, which is known as the joule heating effect. When the ESD pulse cannot be released evenly and effectively by the MOSFET, the contact metal may melt. Further, to effectively control the short channel effect, the shallow junction is applied in a deep-micro device, so that the current density is increased, the joule heating effect becomes severe, and the contact metal melts and passes through the shallow junction; thus, the junction short is caused, the leakage current is observed and the device endurance is affected.

Accordingly, an ESD protection device which is able to solve the above-mentioned problems is deeply desired.

### SUMMARY OF THE INVENTION

The present invention provides an ESD protection device, in which a junction short caused by the contact metal melting and passing through the source and drain junctions is avoided, so that the device endurance is enhanced.

The present invention further provides a method of fabricating an ESD protection device, in which several process steps are added, and a junction short caused by the contact metal melting and passing through the source and drain junctions is avoided, so that the device endurance is enhanced.

The present invention provides an ESD protection device including a substrate, a gate structure, a source region, a drain region and a first implanted region. The gate structure includes a gate dielectric layer and a gate sequentially disposed on the substrate. The source region and the drain region are disposed in the substrate beside the gate structure, and a channel region is disposed therebetween. The first implanted region has the same conductivity type as the drain region. The first implanted region is disposed below the drain region, and the border thereof does not exceed the border of the drain region.

According to an embodiment of the present invention, the shortest distance between the first implanted region and the drain region in the channel length direction is d1, and d1 is greater than 0.

According to an embodiment of the present invention, the ESD protection device further includes a drain contact disposed on the drain region, wherein the shortest distance between the drain contact and the channel region is D1, and D1 is greater than or equal to d1.

According to an embodiment of the present invention, the first implanted region is substantially disposed right below the drain contact.

According to an embodiment of the present invention, the distance between the bottom of the first implanted region and the bottom of the drain region is h1, the distance between the bottom of the first implanted region and the top surface of the substrate is H1, and h1=0.2-0.8 H1.

According to an embodiment of the present invention, the concentration of the first implanted region is lower than the concentration of the drain region.

According to an embodiment of the present invention, the first implanted region, the drain region and the source region are all P-type or N-type.

According to an embodiment of the present invention, the ESD protection device further includes a second implanted region having the same conductivity type as the source region and disposed below the source region, wherein the border of the second implanted region does not exceed the border of the source region.

According to an embodiment of the present invention, the shortest distance between the second implanted region and the source region in the channel length direction is d2, and d2 is greater than 0.

According to an embodiment of the present invention, the ESD protection device further includes a source contact disposed on the source region, wherein the shortest distance between the source contact and the channel region is D2, and D2 is greater than or equal to d2.

According to an embodiment of the present invention, the second implanted region is substantially disposed right below the source contact.

According to an embodiment of the present invention, the distance between the bottom of the second implanted region and the bottom of the source region is h2, the distance between the bottom of the second implanted region and the top surface of the substrate is H2, and h2=0.2-0.8 H2.

According to an embodiment of the present invention, the concentration of the second implanted region is lower than the concentration of the source region.

According to an embodiment of the present invention, the second implanted region, the drain region and the source region are all P-type or N-type.

The present invention further provides a method of fabricating an ESD protection device. First, a gate dielectric layer and a gate are sequentially formed on a substrate, so as to form a gate structure. Thereafter, a source region and a drain region are formed in the substrate beside the gate structure, and a channel region is formed therebetween. Afterwards, a first implanted region is formed in the substrate. The first implanted region has the same conductivity type as the drain region. The first implanted region is formed below the drain region and the border thereof does not exceed the border of the drain region.

According to an embodiment of the present invention, the step of forming the first implanted region is after the step of forming the source region and the drain region.

According to an embodiment of the present invention, the step of forming the first implanted region is before the step of forming the source region and the drain region.

According to an embodiment of the present invention the method of forming the source region and the drain region includes the following steps. First, a first photoresist layer having a first opening is formed on the substrate. Thereafter, a first ion implantation process is performed, so as to form the source region and the drain region. The first photoresist layer is then removed. Further, the method of forming the first implanted region includes the following steps. First, a second photoresist layer having a second opening is formed on the substrate, wherein the second opening is smaller than the first opening. Thereafter, a second ion implantation process is performed, so as to form the first implanted region. The second photoresist layer is then removed.

According to an embodiment of the present invention, the implantation dosage of the second implantation process is 1/200- 1/50 times the implantation dosage of the first ion implantation process.

According to an embodiment of the present invention, the second photoresist layer further has a third opening smaller than the first opening, and the ESD protection device further includes forming a second implanted region below the source region during the step of performing the second implantation process.

The present invention provides an ESD protection device, in which a junction short caused by the contact metal melting and passing through the source and drain junctions is avoided, so that the device endurance is enhanced. Further, the fabrication method can be achieved by adding several process steps.

In order to make the aforementioned and other objects, features and advantages of the present invention comprehensible, a preferred embodiment accompanied with figures is described in detail below.

### BRIEF DESCRIPTION OF THE DRAWINGS

FIG. 1 schematically illustrates a cross-section view of an ESD protection device according to an embodiment of the present invention.

FIG. 2 schematically illustrates a cross-section view of an ESD protection device according to another embodiment of the present invention.

FIG. 3 schematically illustrates a cross-section view of a P-type ESD protection device according to the first embodiment of the present invention.

FIGS. 3A to 3C are schematic cross-section views illustrating a method of fabricating a P-type ESD protection device according to the first embodiment of the present invention.

FIG. 4 schematically illustrates a cross-section view of a P-type ESD protection device according to the second embodiment of the present invention.

FIGS. 4A to 4C are schematic cross-section views illustrating a method of fabricating a P-type ESD protection device according to the second embodiment of the present invention.

FIG. 5 schematically illustrates a cross-section view of an N-type ESD protection device according to the third embodiment of the present invention.

FIG. 6 schematically illustrates a cross-section view of an N-type ESD protection device according to the fourth embodiment of the present invention.

FIG. 7 illustrates an electric relation diagram of the conventional ESD protection device and the ESD protection device of the present invention.

### DESCRIPTION OF EMBODIMENTS

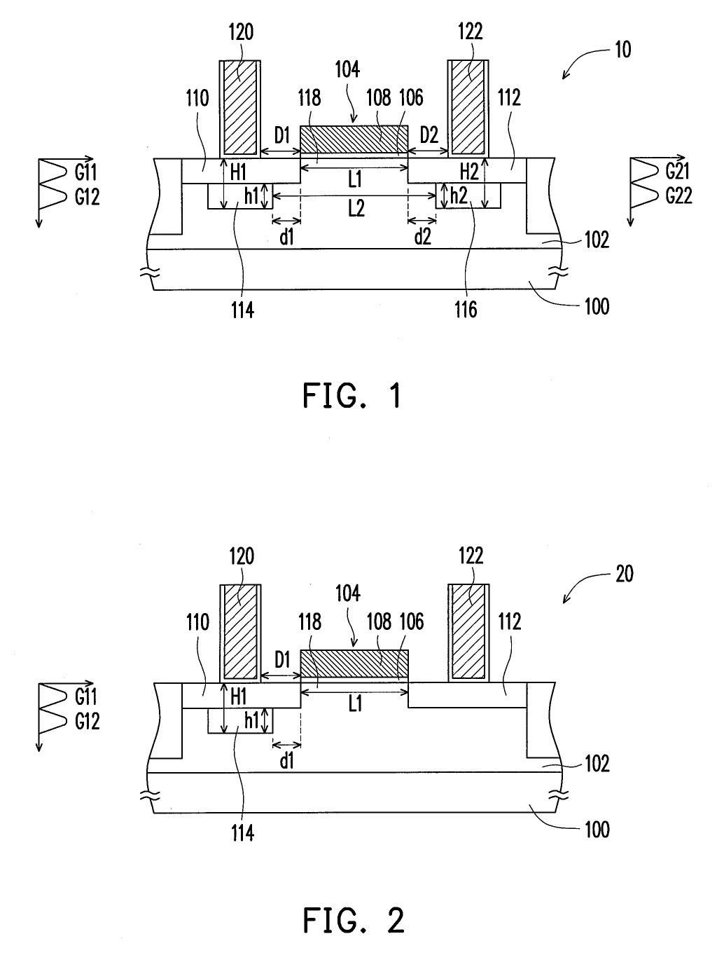

FIG. 1 schematically illustrates a cross-section view of an ESD protection device according to an embodiment of the present invention.

Referring to FIG. 1, an ESD protection device 10 of the present invention includes a substrate 100, a gate structure 104, a drain region 110, a source region 112, a first implanted region 114 and a second implanted region 116. The substrate 100 is an N-type or P-type silicon substrate, for example. In an embodiment, a well 102 having a different conductivity type from the substrate 100 is optionally disposed in the substrate 100, for example. The gate structure 104 includes a gate dielectric layer 106 and a gate 108 sequentially disposed on the substrate 100. The gate dielectric 106 includes silicon oxide, for example. The gate 108 includes a polysilicon with P-type or N-type dopants, for example. The drain region 112 is disposed in the substrate 100 at one side of the gate structure 104. The drain region 110 is disposed in the substrate 100 at the other side of the gate structure 104. The drain region 110 and the source region 112 have a different conductivity type from the substrate 100 or the well 102 in the substrate 100. The drain region 110 and the source region 112 are P-type or N-type doped regions, for example. The drain region 110 and the source region 112 have the same conductivity type and a channel region 118 is disposed therebetween.

The first implanted region 114 of the ESD protection device 10 is for increasing the junction depth of the drain region 110, and the second implanted region 116 of the same is for increasing the junction depth of the source region 112. Therefore, the first implanted region 114, the second implanted region 116, the drain region 110 and the source region 112 have the same conductivity type; that is, all of them are all P-type or N-type.

In the ESD protection device 10, the first implanted region 114 and the second implanted region 116 are respectively for increasing the junction depths of the drain region 110 and the source region 112, and thus, the first implanted region 114 is disposed below the drain region 110 and the border thereof does not exceed the border of the drain region 110, and the second implanted region 116 is disposed below the source region 112 and the border thereof does not exceed the border of the source region 112. In an embodiment, the shortest distance between the first implanted region 114 and the drain region 110 in the channel length direction is d1, and d1 is greater than 0. The shortest distance between the second implanted region 116 and the source region 112 in the channel length direction is d2, and d2 is greater than 0. In other words, the distance between the first implanted region 114 and the second implanted region 116 is L1, the length of the channel region 118 is L2, and L2 is greater than L1 so that the punch through and leakage problems derived from the expansion of the depletion region is reduced. In an embodiment, the semiconductor device includes a core PMOS device and an ESD PMOS device, wherein the ESD PMOS device has the P-type first implanted region 114 and the P-type second implanted region 116, but the core PMOS device does not have the P-type first implanted region and the P-type second implanted region disposed respectively below the drain and source regions thereof.

In another embodiment, the ESD protection device 10 further includes a drain contact 120 and a source contact 122 respectively disposed on the drain region 110 and the source region 112. The drain contact 120 and the source contact 122 may be tungsten layers or doped polysilicon layers. An adhesion layer can be formed between the tungsten layer and the source region 110 or the drain region 112. The adhesion layer includes titanium (Ti), tantalum (Ta), titanium nitride (TiN), tantalum nitride (TaN) or combinations thereof, for example. The shortest distance between the drain contact 120 and the channel region 118 is D1, and the shortest distance between the source contact 122 and the channel region 118 is D2, wherein D1 is greater than or equal to d1, and D2 is greater than or equal to d2. That is, 0<d1≦D1 and 0<d2≦D2. In another embodiment, the first implanted region 114 is substantially disposed right below the drain contact 120, and the second implanted region 116 is substantially disposed right below the source contact 122, so that the junction depths of the drain region 110 and the source region 112 are increased, the time that contact metal melts and passes through the junction is longer, and thus, the endurance of the ESD protection device is enhanced.

In the ESD protection device 10, the first implanted region 114 and the second implanted region 116 are respectively for increasing the junction depths of the drain region 110 and the source region 112. The distance between the bottom of the first implanted region 114 and the top surface of the substrate 100 is H1. The distance between the bottom of the second implanted region 116 and the top surface of the substrate 100 is H2. The junction depth of the first implanted region 114, i.e. the distance between the bottom of the drain region 110 and the bottom of the first implanted region 114, is h1. The junction depth of the second implanted region 116, i.e. the distance between the bottom of the source region 112 and the bottom of the second implanted region 116, is h2. In an embodiment, h1=0.2-0.8 H1 and h2=0.2-0.8 H2. When h1<0.2 H1 and/or h2<0.2 H2, the increased junction depth is limited, and the contact metal passing through the junction cannot be effectively avoided.

In the ESD protection device 10, the concentration of the first implanted region 114 is lower than that of the drain region 110, and the concentration of the second implanted region 116 is lower than that of the source region 112. In an embodiment, the dosage of the ion implantation process for forming the first implanted region 114 is 1/200- 1/50 times that for forming the second implanted region 116. In an embodiment, the concentration distribution of the first implanted region 114 is a Gaussian distribution G12, and the concentration distribution of the drain region 110 is a Gaussian distribution G11, but the positions and widths of the Gaussian distributions G11 and G12 are different. Similarly, the concentration distribution of the second implanted region 116 is a Gaussian distribution G22, and the concentration distribution of the source region 112 is a Gaussian distribution G21, but the positions and widths of the Gaussian distributions G21 and G22 are different. That is, the concentration distribution in the region covered by the drain region 110 and the first implanted region 114 includes two Gaussian distributions G11 and G12 in a vertical direction perpendicular to the top surface of the substrate 100. The concentration distribution in the region covered by the source region 112 and the second implanted region 116 includes two Gaussian distributions G21 and G22 in a vertical direction perpendicular to the top surface of the substrate 100.

In the ESD protection device 10, the first implanted region 114 and the second implanted region 116 have the same conductivity type, but the concentrations, depths, areas, implantation energies, dosages and dopants thereof can be the same or different.

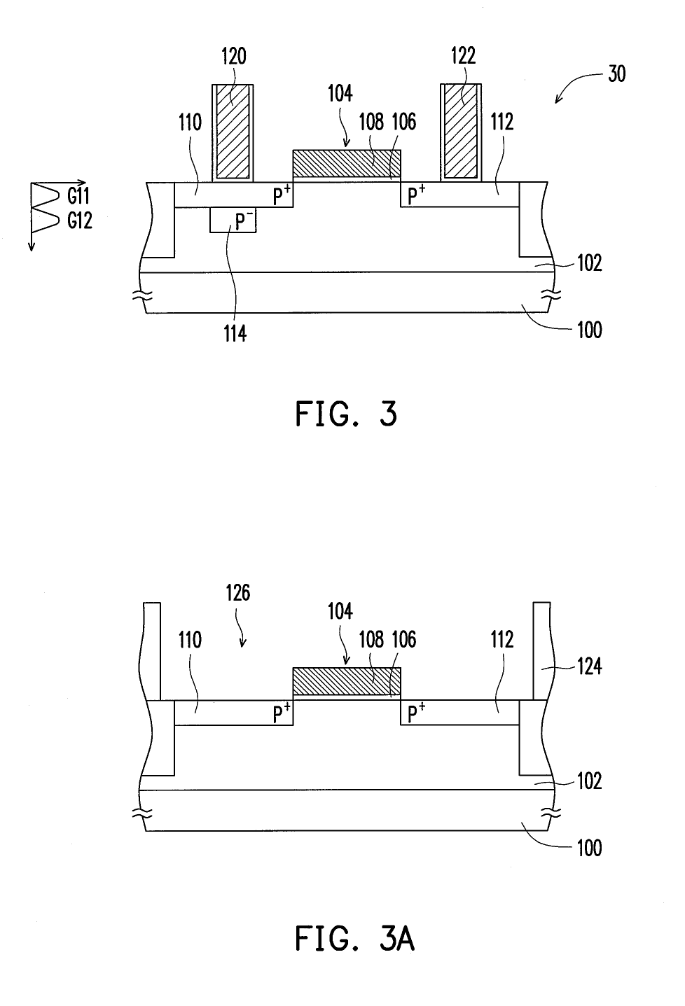

The above-mentioned embodiment is illustrated by exemplifying that the ESD protection device 10 has both the first implanted region 114 and the second implanted region 116. However, the present invention is not limited thereto. In another embodiment, the ESD protection device does not include the second implanted region 116 disposed below the source region 112, and only includes the first implanted region 114 disposed below the drain region 110, as shown in the ESD protection device 20 in FIG. 2 In an embodiment, the semiconductor device includes a core PMOS device and an ESD PMOS device, wherein the core PMOS device does not have the P-type first implanted region and the P-type second implanted region disposed respectively below the drain and source regions thereof, and the ESD PMOS device does not has the P-type second implanted region 116 disposed below the source region 112 thereof either, but the ESD PMOS device has the first P-type implanted region 114 disposed below the drain region 110 thereof.

### First Embodiment

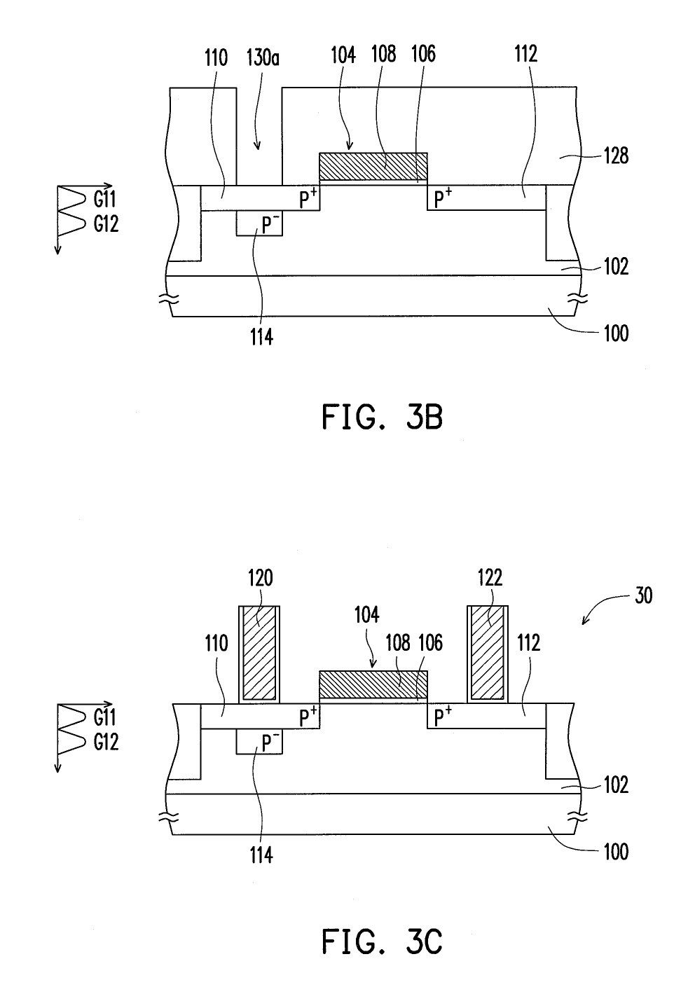

FIG. 3 schematically illustrates a cross-section view of a P-type ESD protection device according to the first embodiment of the present invention.

Referring to FIG. 3, the ESD protection device 30 in the first embodiment includes a P-type substrate 100, an N-type well 102, a gate structure 104, a P-type source region 112 and a P-type drain region 110, a P-type first implanted region 114, a drain contact 120 and a source contact 122. The gate structure 104 includes a gate dielectric layer 106 and a gate 108 sequentially disposed on the substrate 100. The P-type drain region 112 is disposed in the P-type substrate 100 at one side of the gate structure 104. The P-type drain region 110 is disposed in the P-type substrate 100 at the other side of the gate structure 104. The P-type drain region 110 and the P-type source region 112 have the same conductivity type and a channel region 118 is disposed therebetween. The drain contact 120 is disposed on and electronically connected to the drain region 110. The source contact 122 is disposed on and electronically connected to the source region 112. The P-type first implanted region 114 is substantially disposed right below the drain contact 120, and the concentration thereof is lower than that of the drain region 110. The above-mentioned P-type second implanted region 116 is not disposed below the source contact 122.

FIGS. 3A to 3C are schematic cross-section views illustrating a method of fabricating a P-type ESD protection device according to the first embodiment of the present invention.

Referring to FIG. 3A, the method of fabricating the ESD protection device 30 includes forming an N-type well 102 in a P-type substrate 100 and forming a gate structure 104 on the P-type substrate 100. Thereafter, a first photoresist layer 124 is formed on the P-type substrate 100, and a lithography process is then performed to cover the NMOS area and expose the PMOS area, so as to form an opening 126. Afterwards, an ion implantation process is performed, followed by an annealing process, so as to form a P-type drain region 110 and a P-type source region 112 in the N-type well 102. In the ion implantation process, the implanted ions includes boron, the implantation energy is between 3-15 KeV, and the implantation dosage is between 5×10¹⁴-5×10¹⁵/cm², for example.

Referring to FIG. 3B, the first photoresist layer 124 is removed. Thereafter, a second photoresist layer 128 is formed. A lithography process is then performed, so that the core PMOS and NMOS device area and the ESD NMOS device area are covered by the second photoresist layer 128 and only an opening 130a is formed therein to expose a portion of the ESD PMOS device area. The opening 130a is smaller than the opening 126 and only exposes a portion of the P-type drain region 110. The opening 130a does not expose the P-type source region 112. Afterwards, an ion implantation process is performed, followed by an annealing process, so as to form a P-type first implanted region 114 below the P-type drain region 110. In the ion implantation process, the implanted ions includes boron, the implantation energy is between 30-80 KeV, and the implantation dosage is between 3×10¹³-8×10¹³/cm², for example. In this embodiment, the difference between the core PMOS device and the ESD PMOS device is that the core PMOS device does not have the P-type first implanted region disposed below the drain and source regions thereof, and the ESD PMOS device does not has the above-mentioned P-type second implanted region 116 disposed below the source region 112 thereof either, but the ESD PMOS device has the first P-type implanted region 114 disposed below the drain region 110 thereof.

Referring to FIG. 3C, the second photoresist layer 128 is removed. Thereafter, a drain contact 120 is formed right above the first implanted region 114, and a source contact 122 is formed on the source region 112.

In the first embodiment, the P-type first implanted region 114 is formed after the P-type drain region 110 and the P-type source region 112 are formed. However, the present invention is not limited thereto. In another embodiment (not shown), the P-type first implanted region 114 is formed before the P-type drain region 110 and the P-type source region 112 are formed.

### Second Embodiment

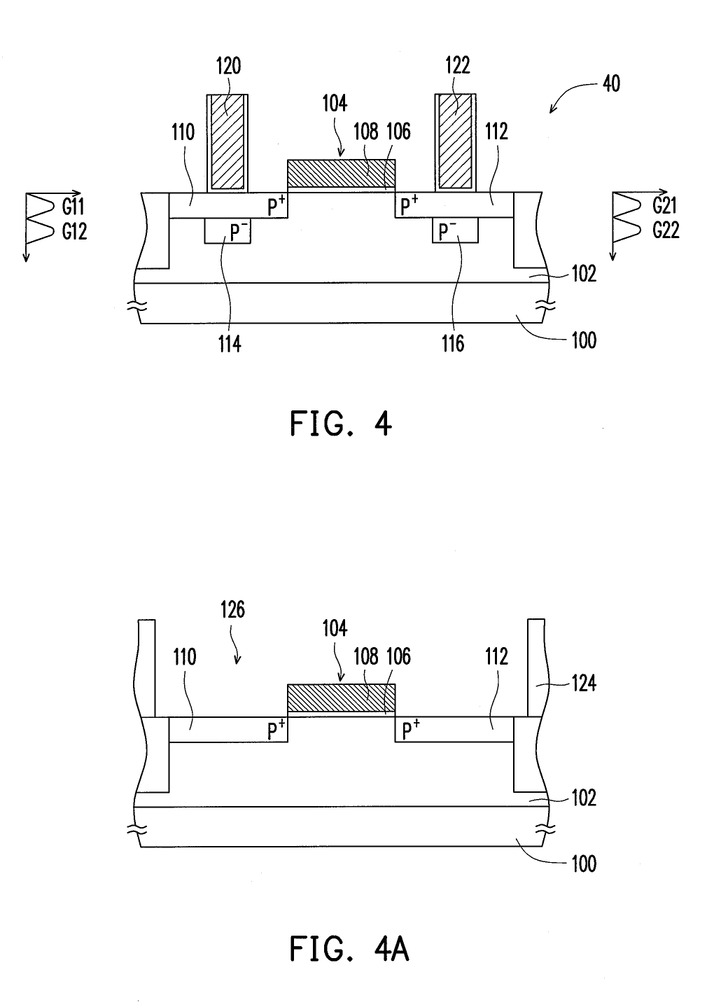

FIG. 4 schematically illustrates a cross-section view of a P-type ESD protection device according to the second embodiment of the present invention.

Referring to FIG. 4, the ESD protection device 40 in the second embodiment is similar to the ESD protection device 30 in the first embodiment. The ESD protection device 40 not only includes a P-type substrate 100, an N-type well 102, a gate structure 104, a P-type source region 112 and a P-type drain region 110, a P-type first implanted region 114, a drain contact 120 and a source contact 122, but also includes a P-type second implanted region 116. The P-type second implanted region 116 is substantially disposed right below the source contact 122, and the concentration thereof is lower than that of the source region 112.

FIGS. 4A to 4C are schematic cross-section views illustrating a method of fabricating a P-type ESD protection device according to the second embodiment of the present invention.

Referring to FIGS. 4A and 4B, after an N-type well 102, a gate structure 104, a P-type drain region 110 and a P-type source region 112 are formed based on the method of fabricating the ESD protection device 30 in the first embodiment, a second photoresist layer 128a is formed on the P-type substrate 100. A lithography process is then performed, so that the core PMOS and NMOS device area and the ESD NMOS device area are covered by the second photoresist layer 128a and only openings 130a and 130b are formed therein to expose a portion of the ESD PMOS device area. The openings 130a and 130b not only expose a portion of the P-type drain region 110, but also expose a portion of the P-type source region 112. Therefore, a P-type first implanted region 114 and a P-type second implanted region 116 are respectively formed below the P-type drain region 110 and the P-type source region 112 at the same time. In this embodiment, the difference between the core PMOS device and the ESD PMOS device is that the ESD PMOS device has the P-type first implanted region 114 and the P-type second implanted region 116, but the core PMOS device does not have the P-type first implanted region and the P-type second implanted region disposed respectively below the drain and source regions thereof.

Referring to FIG. 4C, the second photoresist layer 128a is removed. Thereafter, a drain contact 120 is formed right above the first implanted region 114, and a source contact 122 is formed right above the second implanted region 116.

In the second embodiment, the P-type first implanted region 114 and the P-type second implanted region 116 are formed after the P-type drain region 110 and the P-type source region 112 are formed. However, the present invention is not limited thereto. In another embodiment (not shown), the P-type first implanted region 114 and the P-type second implanted region 116 are formed before the P-type drain region 110 and the P-type source region 112 are formed.

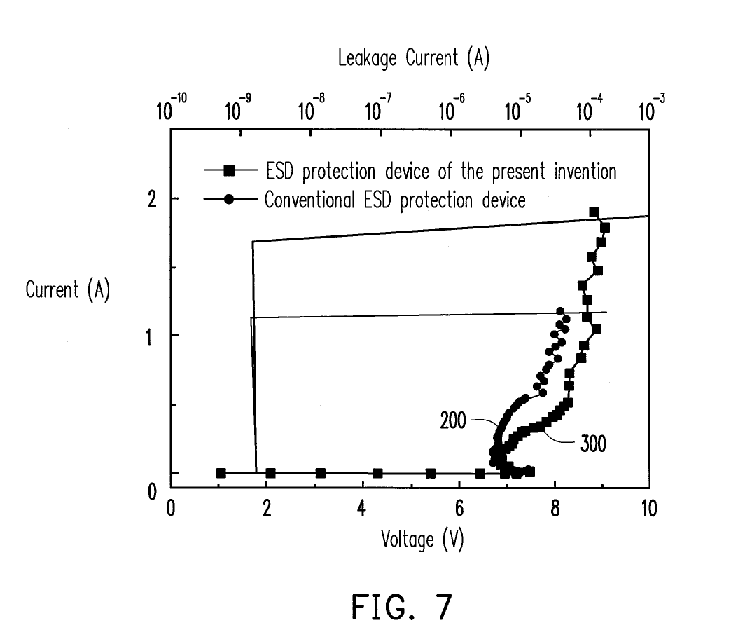

FIG. 7 illustrates an electric relation diagram of the conventional ESD protection device and the ESD protection device of the present invention.

Referring to FIG. 7, the line 200 illustrates the testing result of the P-type ESD protection device 40 in the second embodiment, and the line 300 illustrates the testing result of the conventional ESD protection device without the first and second implanted regions. As shown in FIG. 7, the ESD protection device of the present invention, in which the first and second implanted regions are formed below the drain and source regions, can enhance 40% of the device endurance.

### Third Embodiment

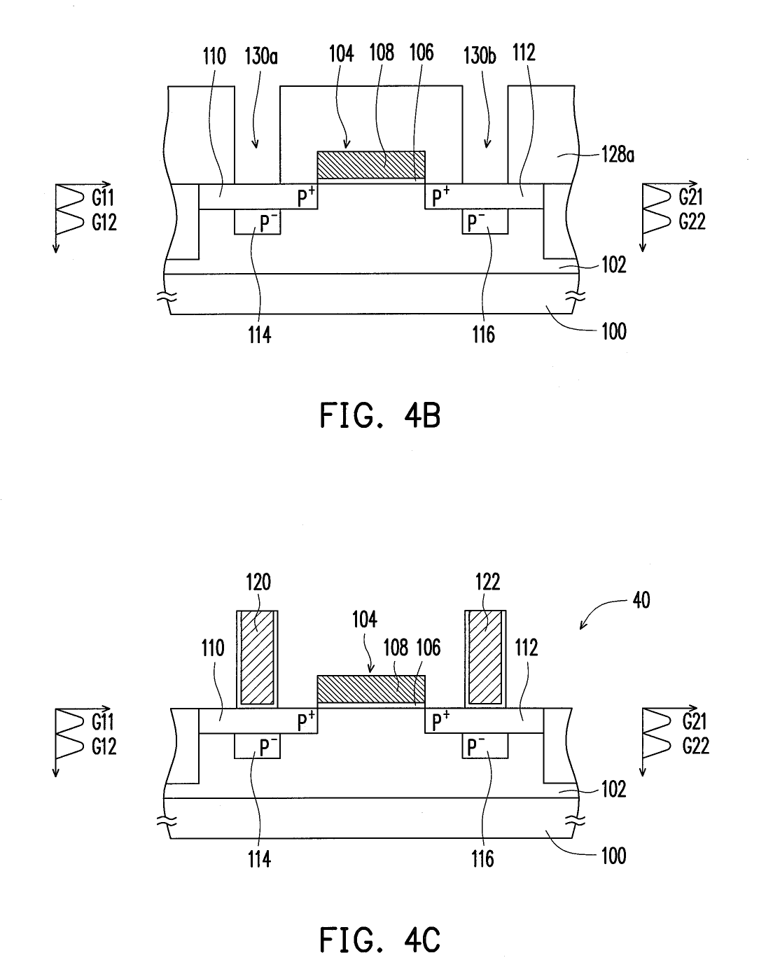

FIG. 5 schematically illustrates a cross-section view of an N-type ESD protection device according to the third embodiment of the present invention.

Referring to FIG. 5, the ESD protection device 50 in the third embodiment includes a P-type substrate 100, a gate structure 104, an N-type source region 112 and an N-type drain region 110, an N-type first implanted region 114, a drain contact 120 and a source contact 122. The ESD protection device 50 in the third embodiment is similar to the ESD protection device 30 in the first embodiment in terms of the components, the relations and forming methods thereof. The difference between them is that an well 102 is not formed in the substrate 100, and the source region 112, the drain region 110 and the first implanted region 114 include N-type dopants instead; thus, the details are not iterated.

### Fourth Embodiment

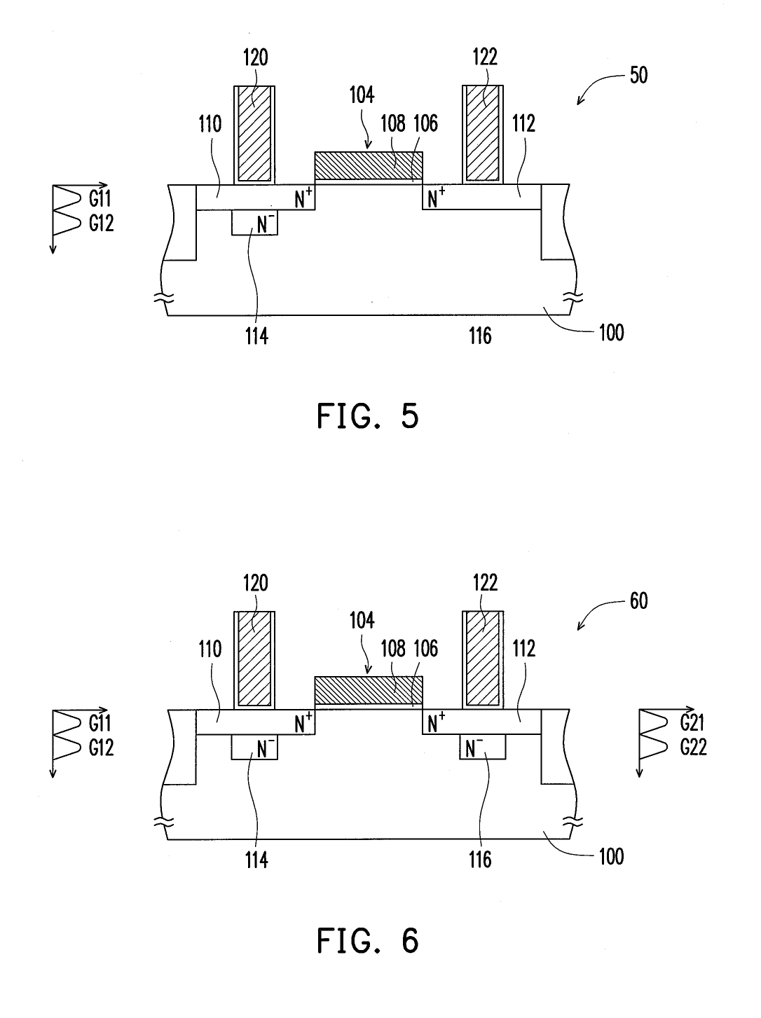

FIG. 6 schematically illustrates a cross-section view of an N-type ESD protection device according to the fourth embodiment of the present invention.

Referring to FIG. 6, the ESD protection device 60 in the fourth embodiment includes a P-type substrate 100, a gate structure 104, an N-type source region 112 and an N-type drain region 110, an N-type first implanted region 114, an N-type implanted region 116, a drain contact 120 and a source contact 122. The ESD protection device 60 in the fourth embodiment is similar to the ESD protection device 40 in the second embodiment in terms of the components, the relations and forming methods thereof. The difference between them is that an well 102 is not formed in the substrate 100, and the source region 112, the drain region 110, the first implanted region 114 and the second implanted region 116 include N-type dopants instead; thus, the details are not iterated.

In summary, in the ESD protection device of the present invention, the implanted regions are formed below the source and drain regions, wherein the implanted regions have the same conductivity type as the source and drain regions but the concentration thereof is lower than that of the source and drain regions. Therefore, a junction short caused by the contact metal melting and passing through the source and drain junctions can be avoided, so that the device endurance is enhanced. Further, the method in accordance with the present invention is simple and competitive, and the above-mentioned performance can be easily achieved by adding several process steps.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. An ESD protection device, comprising:
a substrate;
a gate structure, comprising a gate dielectric layer and a gate sequentially disposed on the substrate;
a source region, disposed in the substrate at one side of the gate structure;
a drain region, disposed in the substrate at the other side of the gate structure, wherein a channel region is disposed between the source region and the drain region; and
a first implanted region, having the same conductivity type as the drain region and disposed below the drain region, wherein a border of the first implanted region does not exceed a border of the drain region.

2. The device of claim 1, wherein the shortest distance between the first implanted region and the drain region in a channel length direction is d1, and d1 is greater than 0.

3. The device of claim 2, further comprising a drain contact disposed on the drain region, wherein the shortest distance between the drain contact and the channel region is D1, and D1 is greater than or equal to d1.

4. The device of claim 3, wherein the first implanted region is substantially disposed right below the drain contact.

5. The device of claim 1, wherein a distance between a bottom of the first implanted region and a bottom of the drain region is h1, a distance between the bottom of the first implanted region and a top surface of the substrate is H1, and h1=0.2-0.8 H1.

6. The device of claim 1, wherein a concentration of the first implanted region is lower than a concentration of the drain region.

7. The device of claim 1, wherein the first implanted region, the drain region and the source region are all P-type or N-type.

8. The device of claim 1, further comprising a second implanted region having the same conductivity type as the source region and disposed below the source region, wherein a border of the second implanted region does not exceed a border of the source region.

9. The device of claim 8, wherein the shortest distance between the second implanted region and the source region in a channel length direction is d2, and d2 is greater than 0.

10. The device of claim 9, further comprising a source contact disposed on the source region, wherein the shortest distance between the source contact and the channel region is D2, and D2 is greater than or equal to d2.

11. The device of claim 10, wherein the second implanted region is substantially disposed right below the source contact.

12. The device of claim 8, wherein a distance between a bottom of the second implanted region and a bottom of the source region is h2, a distance between the bottom of the second implanted region and a top surface of the substrate is H2, and h2=0.2-0.8 H2.

13. The device of claim 8, wherein a concentration of the second implanted region is lower than a concentration of the source region.

14. The device of claim 1, wherein the second implanted region, the drain region and the source region are all P-type or N-type.

15. A method of fabricating an ESD protection device, comprising:
forming a gate dielectric layer and a gate sequentially on a substrate, so as to form a gate structure;
forming a source region and a drain region in the substrate beside the gate structure, wherein a channel region is formed between the source region and the drain region; and
forming a first implanted region in the substrate, wherein the first implanted region has the same conductivity type as the drain region, and the first implanted region is formed below the drain region and a border thereof does not exceed a border of the drain region.

16. The method of claim 15, wherein the step of forming the first implanted region is after the step of forming the source region and the drain region.

17. The method of claim 15, wherein the step of forming the first implanted region is before the step of forming the source region and the drain region.

18. The method of claim 15, wherein the step of forming the source region and the drain region comprises:
forming a first photoresist layer on the substrate, the first photoresist layer having a first opening;
performing a first ion implantation process, so as to form the source region and the drain region; and
removing the first photoresist layer; and
wherein the step of forming the first implanted region comprises:
forming a second photoresist layer on the substrate, the second photoresist layer having a second opening, wherein the second opening is smaller than the first opening;
performing a second ion implantation process, so as to form the first implanted region; and
removing the second photoresist layer.

19. The method of claim 18, wherein an implantation dosage of the second implantation process is 1/200- 1/50 times an implantation dosage of the first ion implantation process.

20. The method of claim 18, wherein the second photoresist layer further has a third opening smaller than the first opening, further comprising forming a second implanted region below the source region during the step of performing the second implantation process.
